(19) United States
(12) Patent Application Publication
(10) Pub. No.: US 2026/0066917 A1
(43) Pub. Date: Mar. 5, 2026

(54) SYSTEMS AND METHODS FOR PROVIDING MULTIPLE STABLE REFERENCE VOLTAGES

(71) Applicant: Qorvo US, Inc., Greensboro, NC (US)

(72) Inventors: Jeroen Cornelis Kuenen, Beuningen (NL); Theo Band, Oostzaan (NL); Anne Stellinga, Driebergen (NL); Hendrik Arend Visser, Wijchen (NL); Marie Dessier, den Haag (NL)

(21) Appl. No.: 19/279,100

(22) Filed: Jul. 24, 2025

Related U.S. Application Data
(60) Provisional application No. 63/690,940, filed on Sep. 5, 2024.
(60) Provisional application No. 63/748,490, filed on Jan. 23, 2025.

(51) Int. Cl. H03M 1/36; G05F 1/46; H03M 1/06; H03M 1/10

(52) U.S. Cl. CPC H03M 1/362; G05F 1/468; H03M 1/0604; H03M 1/1014

(57) ABSTRACT

Systems and methods for providing multiple stable reference voltages are disclosed. In one aspect, a bandgap reference circuit generates a first reference voltage, which is calibrated with an adjustable resistor bank. Settings for this adjustable resistor bank may be stored in a memory and reused at multiple locations with theoretically identical resistor banks for other circuits requiring reference voltages. Recognizing that there may be voltage network variations induced by distances from bandgap reference circuit, process variations between resistor banks, or the like, each resistor bank may be separately calibrated, and settings stored in memory. By providing separate resistor banks for each location that needs a reference voltage, the need for duplicative and space intensive bandgap reference circuits is minimized. Further, by providing separate resistor banks, variations in the local voltage are minimized providing more stable and reliable operation of circuits in the die.

### PRIORITY APPLICATIONS

The present application claims priority to U.S. Provisional Patent Application Ser. No. 63/690,940 filed on Sep. 5, 2024, and entitled “LOW-NOISE ACCURATE REFERENCE VOLTAGE DISTRIBUTION,” the disclosure of which is incorporated herein by reference in its entirety.

The present application claims priority to U.S. Provisional Patent Application Ser. No. 63/748,490, filed Jan. 23, 2025, and entitled “SYSTEMS AND METHODS FOR PROVIDING MULTIPLE STABLE REFERENCE VOLTAGES,” which is incorporated herein by reference in its entirety

### BACKGROUND

### I. Field of the Disclosure The technology of the disclosure relates generally to providing stable reference voltages at multiple locations on a single die.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, the complexity of the transceivers enabling wireless communication have increased. In particular, the front-end modules (FEMs) of the transceivers may have multiple circuits requiring fixed voltages for operation compliant with relevant wireless standards. Being able to provide reference voltages at multiple locations across a die provides room for innovation.

### SUMMARY

Aspects disclosed in the detailed description include systems and methods for providing multiple stable reference voltages. In particular, a bandgap reference circuit generates a first reference voltage, which is calibrated with an adjustable resistor bank. Settings for this adjustable resistor bank may be stored in a memory and reused at multiple locations with theoretically identical resistor banks for other circuits requiring reference voltages. Recognizing that there may be voltage network variations induced by distances from bandgap reference circuits, process variations between resistor banks, or the like, each resistor bank may be separately calibrated and settings stored in memory. By providing separate resistor banks for each location that needs a reference voltage, the need for duplicative and space-intensive bandgap reference circuits is minimized. Further, by providing separate resistor banks, variations in the local voltage are minimized providing more stable and reliable operation of circuits in the die.

In this regard, in one aspect, a die is disclosed. The die includes a bandgap reference circuit configured to output a known bandgap reference voltage (Vbandgap), a first current reference circuit comprising a first transistor and a first resistor array, the first current reference circuit coupled to the bandgap reference circuit, and a second current reference circuit associated with a sub-module in the die, the second current reference circuit comprising a second transistor and a second resistor array.

In another aspect, a transceiver chain is disclosed. The transceiver chain includes a baseband processor (BBP), a transceiver circuit coupled to the BBP, and a front-end module (FEM) comprising a die. The die includes a bandgap reference circuit configured to output a known bandgap reference voltage (Vbandgap), a first current reference circuit comprising a first transistor and a first resistor array, the first current reference circuit coupled to the bandgap reference circuit, and a second current reference circuit associated with a sub-module in the die, the second current reference circuit comprising a second transistor and a second resistor array.

In another aspect, a method is disclosed. The method includes providing a bandgap current to a first current reference circuit, adjusting a first resistor array in the first current reference circuit to provide a reference voltage, measuring resistance at a second current reference circuit, and adjusting the resistance at the second current reference circuit.

### BRIEF DESCRIPTION OF THE DRAWINGS

FIG. 1 is a block diagram of a front-end module (FEM) having a plurality of circuits that operate using a referenced voltage;

FIG. 2 is a block diagram of a die with resistor banks at each location requiring a reference voltage, wherein the resistor banks share a single calibration scheme based on a primary resistor bank associated with a bandgap reference circuit;

FIG. 3 is a block diagram of a die with resistors banks separately calibrated by a control circuit and having the separate settings stored in memory;

FIG. 4 is a flowchart illustrating an exemplary process for calibrating and using the reference banks of the present disclosure to provide reference voltages at multiple locations on a die without the need for multiple bandgap reference circuits; and

FIG. 5 is a block diagram of a wireless communication device, which may include the die of FIG. 1 having the resistor banks of FIG. 2 or 3 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled”to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include systems and methods for providing multiple stable reference voltages. In particular, a bandgap reference circuit generates a first reference voltage, which is calibrated with an adjustable resistor bank. Settings for this adjustable resistor bank may be stored in a memory and reused at multiple locations with theoretically identical resistor banks for other circuits requiring reference voltages. Recognizing that there may be voltage network variations induced by distances from bandgap reference circuit, process variations between resistor banks, or the like, each resistor bank may be separately calibrated, and settings stored in memory. By providing separate resistor banks for each location that needs a reference voltage, the need for duplicative and space intensive bandgap reference circuits is minimized. Further, by providing separate resistor banks, variations in the local voltage are minimized providing more stable and reliable operation of circuits in the die.

While the present disclosure is suited for any die or module that has a need for multiple stable reference voltages, the present discussion will focus on a front-end module (FEM) to help illustrate the teachings of the present disclosure. This choice of FEM is not intended to be limiting.

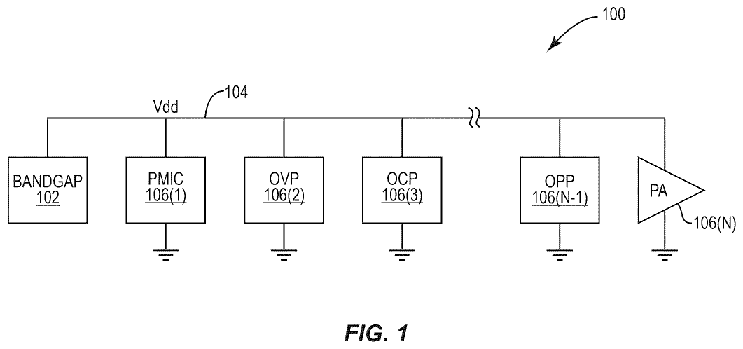

In this regard, FIG. 1 illustrates a die 100, which may be a FEM. The die 100 includes a bandgap reference circuit 102, which generates a stable known voltage (e.g., Vdd), which is distributed on a distribution line or voltage rail 104 to sub-modules 106(1)-106(N) within the die 100. The sub-modules 106(1)-106(N) are functional blocks containing circuits that perform conceptually distinct functions within the die 100 but also rely on a stable known voltage. By way of example, the sub-modules 106(1)-106(N) may include a power management integrated circuit (PMIC) 106(1), an over voltage protection (OVP) loop 106(2), an overcurrent protection (OCP) loop 106(3), an overpower protection (OPP) loop 106(N-1), and a power amplifier (PA) 106(N), low noise amplifiers (LNA), mixers, filters, other receive circuits, voltage controlled oscillators (VCO), phase locked loops (PLLs), digital controlled oscillators (DCOs), or the like. Other sub-modules may also be present and not all of the listed sub-modules are required without departing from the present disclosure.

As device size continues to shrink, there has been movement to have a single bandgap reference circuit 102 provide the known stable voltage to all sub-modules 106(1)-106(N) because bandgap reference circuits generally require a large amount of space relative to the total size of the die 100. Thus, as illustrated in FIG. 1, a voltage rail 104 may transfer the reference voltage to the different sub-modules 106(1)-106(N). In the absence of the present disclosure, transferring the reference voltage to the sub-modules 106(1)-106(N) is susceptible to dynamic ground shifts between the location of the bandgap reference circuit 102 and the specific sub-module 106(1)-106(N). The ground shift comes from the series resistance in the on-chip ground wiring and the supply currents flowing through the ground. Crosstalk between sub-modules 106(1)-106(N) may also arise from capacitive coupling or the like and may induce noise in the local reference voltages. Another approach is to generate a current in bandgap reference circuit 102 and distribute the current using current mirrors (i.e., a current-transfer approach). The reference voltage may then be recreated with the current and a resistor. This approach may reduce crosstalk and eliminate the ground shift issue because the generated voltage is referenced to the local ground. However, this approach lacks reliability because of mismatches in current mirrors and mismatch of resistors. Such mismatches may be a function of process variations or the like.

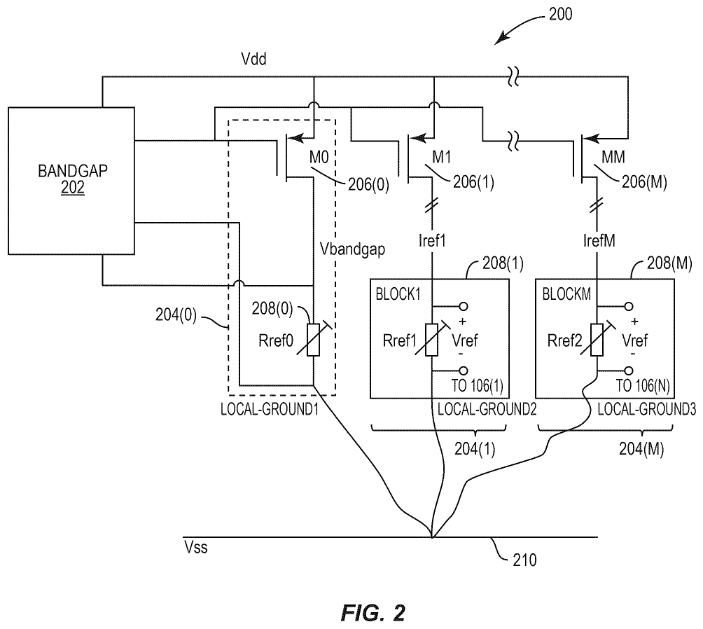

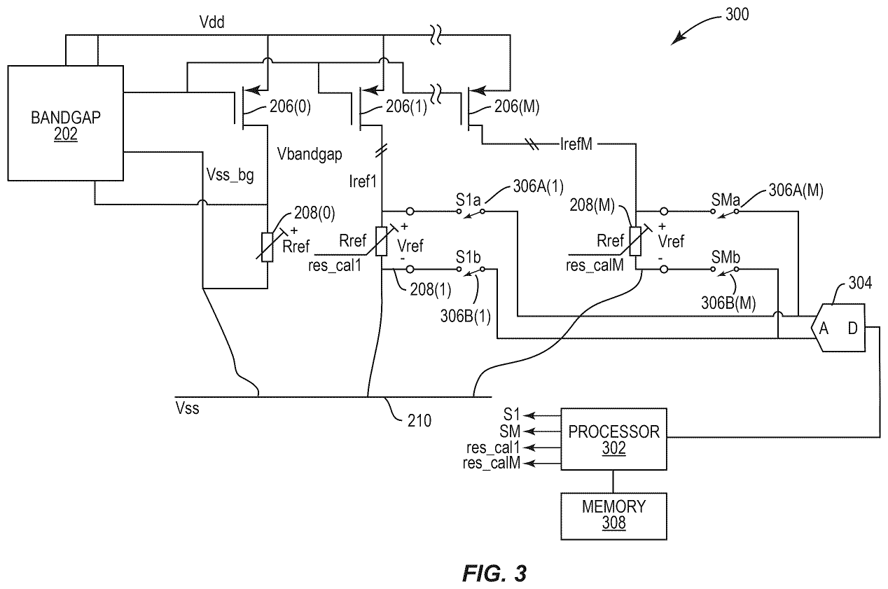

The present disclosure provides two techniques to help address mismatches for the current-transfer approach. The first technique, illustrated in FIG. 2 is to provide a variable resistor array that has identical settings for the resistor array based on calibration of a source variable resistor array associated with the bandgap reference circuit 102. The second technique, illustrated in FIG. 3, is to provide individually calibrated settings for each variable resistor array. By providing individually calibrated settings, mismatch may be corrected, providing a more consistent, stable known reference voltage for each sub-module 106(1)-106(N).

In this regard, FIG. 2 illustrates a die 200 with a bandgap reference circuit 202 that generates the reference voltage Vbandgap. A current reference circuit 204(0) is coupled to the bandgap reference circuit 202 and generates a precise reference voltage. Specifically, a current generated by a transistor 206(0) (M0) with a variable resistor array 208(0) makes the precise reference voltage. This reference voltage is duplicated in other current reference circuits 204(1)-204(M), where the transistors 206(1)-206(M) are matched to generate the same current as the transistor 206(0). This current is brought to the recipient circuit block (e.g., sub-modules 106(1)-106(N)), where it is locally converted to a voltage with variable resistor arrays 208(1)-208(M). By design, the variable resistor arrays 208(0)-208(M) should be identical (i.e., same width, orientation, environment, etc.), however process variations may exist.

Each variable resistor array 208(0)-208(M) may be coupled to a ground (Vss) 210. As illustrated, the connection to ground is a freeform line to indicate the connection is electrically long and has series resistance. Thus, the current consumption at current reference circuits 204(1)-204(M) makes the local ground deviate from the ground at the reference circuit 204(0). Within a die 200, this difference can be ten millivolts (or more) and fluctuates as current is variably consumed. The reference voltage within the current reference circuits 204(1)-204(M) is referenced to the local ground, so Vref is accurate despite the ground shift.

To assist in making Vref local close to the precise Vref of the current reference circuit 204(0), Vbandgap is calibrated during production to get the best accuracy and by adjusting the settings for the variable resistor array 208(0). These settings are then duplicated for the other variable resistor arrays 208(1)-208(M). This approach does result in improvement but still may have empirical variations of approximately eight millivolts.

To boost the accuracy, each individual variable array may be independently calibrated as illustrated in FIG. 3. Many of the structures of 300 are the same as those in die 200 and not renumbered. However, once the settings of the variable resistor array 208(0) are set, an additional calibration may be performed by a control circuit 302. The control circuit 302 (illustrated as a processor in FIG. 3) provides settings to the variable resistor arrays 208(1)-208(M) individually through a signal (e.g., res_cal(1)-res_cal(M)) and measures the resultant resistance using a differential analog to digital converter (ADC) 304. The voltage across the resistor arrays 208(1)-208(M) is measured one resistor array at a time by virtue of the control circuit 302 opening switches 306A(1)-306A(M) and 306B(1)-306B(M) for the variable resistor arrays 208(1)-208(M) whose voltage is not being measured. For example, if the voltage across the variable resistor array 208(1) is being measured, switches 306A(2)-306A(M), 306B(2)-306B(M) are open (and switches 306A(1), 306B(1) are closed). The ADC 304 is coupled to the control circuit 302, and the various possible settings are measured until the measured voltage is approximately equal to the voltage across the variable resistor array 208(0). The settings are then stored in memory 308. It should be appreciated that an optimization algorithm such as Newton-Rapton, binary search, or the like make be used to find the “best”setting.

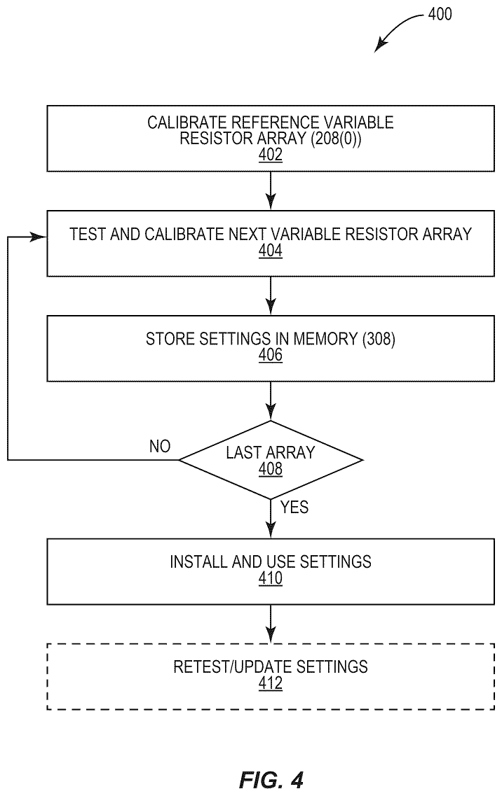

A process 400 for calibration and using the structures of the present disclosure is set forth with reference to FIG. 4. Initially, the process 400 starts by calibrating the reference variable resistor array 208(0) (block 402). These settings for the variable resistor array 208(0) are stored and then provided to the control circuit 302. The control circuit 302 then tests and calibrates the next variable resistor array (block 404) within the variable resistor arrays 208(1)-208(M). Once the proper settings are found, they are stored in memory 308 (block 406). If the last array has not been reached (block 408), then the process 400 iterates back to block 404. If the last array has been calibrated, then the die 300 is installed in a product and used with the settings found in the memory 308 (block 410). Optionally, the control circuit 302 may retest the effective resistance provided by the variable resistor arrays 208(1)-208(M) and update settings (block 412). This optional step may compensate for aging or the like.

The systems and methods for providing multiple stable reference voltages, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

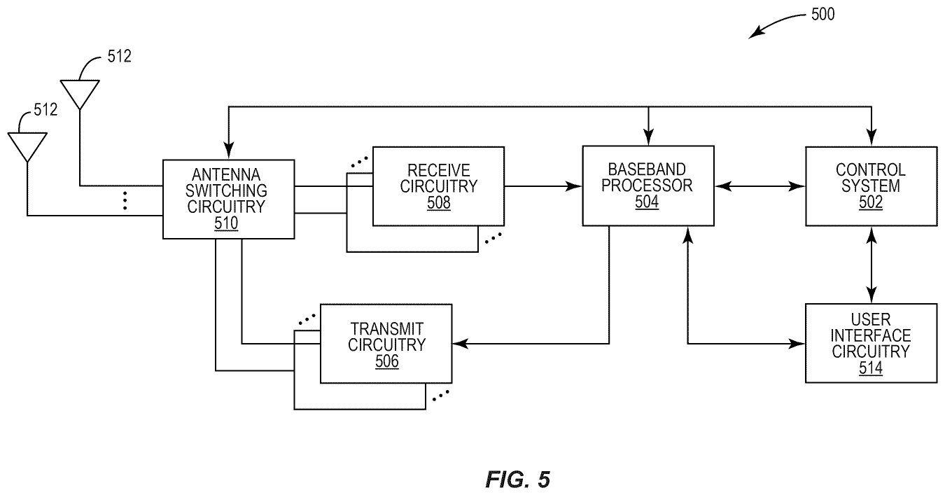

FIG. 5 is a schematic diagram of an exemplary communication device 500 wherein the die 300 can be provided. Herein, the communication device 500 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 500 will generally include a control system 502, a baseband processor 504, transmit circuitry 506, receive circuitry 508, antenna switching circuitry 510, multiple antennas 512, and user interface circuitry 514. It should be appreciated that any of these circuits may be implemented in a die that has the multiple stable reference voltages according to aspects of the present disclosure. In a non-limiting example, the control system 502 can be a field-programmable gate array (FPGA) or an application-specific integrated circuit (ASIC), as an example. In this regard, the control system 502 can include at least a microprocessor(s), an embedded memory circuit(s), and a communication bus interface(s). The receive circuitry 508 receives radio frequency signals via the antennas 512 and through the antenna switching circuitry 510 from one or more base stations. A low noise amplifier and a filter of the receive circuitry 508 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 504 processes the digitized received signal to extract the information or data bits conveyed in the received signal. This processing typically comprises demodulation, decoding, and error correction operations. The baseband processor 504 is generally implemented in one or more digital signal processors (DSPs) and ASICs.

For transmission, the baseband processor 504 receives digitized data, which may represent voice, data, or control information, from the control system 502, which it encodes for transmission. The encoded data is output to the transmit circuitry 506, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 512 through the antenna switching circuitry 510 to the antennas 512. The multiple antennas 512 and the replicated transmit and receive circuitries 506, 508 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A die comprising:
a bandgap reference circuit configured to output a known bandgap reference voltage (Vbandgap);
a first current reference circuit comprising a first transistor and a first resistor array, the first current reference circuit coupled to the bandgap reference circuit; and
a second current reference circuit associated with a sub-module in the die, the second current reference circuit comprising a second transistor and a second resistor array.

2. The die of claim 1, wherein the first resistor array and the second resistor array share resistor settings such that the second resistor array provides approximately identical resistance as the first resistor array.

3. The die of claim 1, wherein the first resistor array has first settings to determine a first resistance, and the second resistor array has second settings to determine a second resistance different than the first settings.

4. The die of claim 1, further comprising a control circuit coupled to the first resistor array and the second resistor array and configured to provide settings for the first resistor array and the second resistor array.

5. The die of claim 4, further comprising a differential analog to digital converter (ADC) coupled to the second resistor array and configured to measure an effective voltage across the second resistor array.

6. The die of claim 5, wherein the control circuit is further configured to calibrate the second resistor array based on signals from the differential ADC.

7. The die of claim 1, further comprising the sub-module, wherein the second current reference circuit provides a stable reference voltage source for the sub-module.

8. The die of claim 7, wherein the sub-module is selected from a group comprising a power management integrated circuit, a protection loop, a receive circuit, a frequency generation circuit, a low noise amplifier, a mixer, a filter, a voltage controlled oscillator, a digital controlled oscillator, a phase locked loop, and a power amplifier.

9. The die of claim 1, further comprising a third reference current circuit coupled to the bandgap reference circuit.

10. The die of claim 1, wherein the second current reference circuit is spaced from the bandgap reference circuit.

11. The die of claim 1 integrated into a front-end module (FEM).

12. A transceiver chain comprising:
a baseband processor (BBP);
a transceiver circuit coupled to the BBP; and
a front-end module (FEM) comprising a die, the die comprising:
a bandgap reference circuit configured to output a known bandgap reference voltage (Vbandgap);
a first current reference circuit comprising a first transistor and a first resistor array, the first current reference circuit coupled to the bandgap reference circuit; and
a second current reference circuit associated with a sub-module in the die, the second current reference circuit comprising a second transistor and a second resistor array.

13. A method comprising:
providing a bandgap current to a first current reference circuit;
adjusting a first resistor array in the first current reference circuit to provide a reference voltage;
measuring voltage at a second current reference circuit; and
adjusting a resistance at the second current reference circuit responsive to voltage at the second current reference circuit to cause the voltage at the second current reference circuit to match approximately the reference voltage.

14. The method of claim 13, wherein measuring voltage comprises using a differential analog to digital converter.

15. The method of claim 13, wherein adjusting the resistance comprises adjusting a second resistor array.

16. The method of claim 15, further comprising finding an optimal set of settings for the second resistor array.

17. The method of claim 16, further comprising storing the optimal set of settings.
